(19) United States
(12) Patent Application Publication
(10) Pub. No.: US 2026/0191015 A1
(43) Pub. Date: Jul. 2, 2026

(54) SEMICONDUCTOR PACKAGE

(71) Applicant: ELSPES Inc., Daejeon (KR)

(72) Inventors: Seunggu LIM, Hwaseong-si (KR); Wisnu MURTI, Hwaseong-si (KR); Yeong Lyeol PARK, Yongin-si (KR)

(21) Appl. No.: 19/086,189

(22) Filed: Mar. 21, 2025

(30) Foreign Application Priority Data
Dec. 30, 2024 (KR) 10-2024-0201025

(51) Int. Cl. H10W 44/20; H10W 70/60; H10W 70/65; H10W 90/00

(52) U.S. Cl. CPC H10W 44/20; H10W 70/611; H10W 70/65; H10W 90/00; H10W 44/223

(57) ABSTRACT

The present invention relates to a semiconductor package. The semiconductor package of the present invention includes a package substrate, a first semiconductor die disposed on the package substrate, a second semiconductor die disposed on the package substrate to be spaced apart from the first semiconductor die, and at least one capacitor disposed on at least one electrical path between the first semiconductor die and the second semiconductor die, wherein the at least one capacitor includes a first pad or bump connected to the first semiconductor die and a second pad or bump connected to the second semiconductor die, and alternating current (AC)-couples the first semiconductor die and the second semiconductor die, thereby enhancing electromagnetic interference (EMI) shielding performance of chip-to-chip communication and improving signal integrity.

### CROSS-REFERENCE TO RELATED APPLICATION

This application claims priority to and the benefit of Korean Patent Application No. 2024-0201025, filed on December 30, 2024, the disclosure of which is incorporated herein by reference in its entirety.

### BACKGROUND

### 1. Field of the Invention

The present invention relates to a semiconductor package, and more particularly, to a semiconductor package including a coupling capacitor.

### 2. Discussion of Related Art

The recent rapid advancement of portable electronic devices, such as smartphones, tablets, and wearable devices, requires these devices to become smaller while delivering higher performance and consuming less power. Accordingly, semiconductor devices are being developed to keep up with the trend of miniaturization and high integration in electronic devices, but, in conventional multi-chip designs, issues such as increased interconnection complexity between components, data transmission delays, and higher power consumption arise.

To address these issues, a system-on-chip (SoC) in which various processing devices, including a central processing unit (CPU), a graphics processing unit (GPU), a digital signal processor (DSP), a neural processing unit (NPU), and radio frequency (RF) circuits, are integrated with a long-term evolution (LTE)/5G communication modem, memory blocks, and the like into a single chip to reduce the interconnection complexity between components while enhancing performance and power efficiency, has been proposed. However, in SoC design, there is a constraint that heterogeneous components must be manufactured in a single process. For example, some components require a 14 nm process, whereas other components can be sufficiently implemented using a 28 nm or 40 nm process. In this case, when all components are integrated using a 14 nm process, excessive resources are wasted on chips that could have been efficiently produced with a 28 nm or 40 nm process. In addition, heterogeneous components designed based on different materials require processes optimized for the characteristics of each material, and when these heterogeneous components are implemented through a single process, both manufacturing and design efficiencies decrease.

Accordingly, there is a need for technology to address the above-described issues.

Meanwhile, the above-described background art is technical information possessed by the inventor for derivation of the present invention or acquired by the inventor during the derivation of the present invention, and is not necessarily considered to be a known technology open to the general public prior to the filing of the present invention.

### Prior-Art Documents

### Patent Document

(Patent Document 1) US Patent Publication No. 2013-0134607 (May 30, 2013)

### SUMMARY OF THE INVENTION

The present invention is directed to providing a semiconductor package that enables the integration and interconnection of heterogeneous chips on a single substrate.

The present invention is also directed to providing a semiconductor package that enables high-speed signal transmission in chip-to-chip communication while reducing cross talk and common mode noise by interconnecting a plurality of semiconductor dies through a coupling capacitor.

The present invention is also directed to providing a semiconductor package that enables the integration of semiconductor dies with a higher density by including a coupling capacitor disposed in a package substrate or an interposer.

Objectives of the present invention are not limited to the above-described objectives, and other objectives that are not described herein will be apparently understood by those skilled in the art from the following description.

According to an aspect of the present invention, there is provided a semiconductor package including a package substrate, a first semiconductor die disposed on the package substrate, a second semiconductor die disposed on the package substrate to be spaced apart from the first semiconductor die, and at least one capacitor disposed on at least one electrical path between the first semiconductor die and the second semiconductor die, wherein the at least one capacitor includes a first pad or bump connected to the first semiconductor die and a second pad or bump connected to the second semiconductor die, and alternating current (AC)-couples the first semiconductor die and the second semiconductor die.

According to another aspect of the present invention, the at least one capacitor may be disposed in the package substrate.

According to still another aspect of the present invention, the semiconductor package may further include a passivation layer disposed on the at least one capacitor, a first bridge wiring disposed between the first semiconductor die and the first pad or bump, and a second bridge wiring disposed between the second semiconductor die and the second pad or bump.

According to yet another aspect of the present invention, the first pad or bump and the second pad or bump may be disposed on the at least one capacitor, and the first pad or bump may be directly connected to a bump or pad disposed below the first semiconductor die, or the second pad or bump may be directly connected to a bump or pad disposed below the second semiconductor die.

According to yet another aspect of the present invention, the semiconductor package may further include an interposer disposed between the first and second semiconductor dies and the package substrate, wherein the at least one capacitor may be disposed in the interposer.

According to yet another aspect of the present invention, the at least one capacitor may be embedded in the interposer, and the interposer may include at least one of a first via formed to pass through between a bump or pad disposed below the first semiconductor die and the first pad, and a second via formed to pass through between a bump or pad disposed below the second semiconductor die and the second pad.

According to yet another aspect of the present invention, the at least one capacitor may be disposed as a plurality of capacitors on the at least one electrical path, and the plurality of capacitors disposed on the at least one electrical path may be connected in parallel.

According to yet another aspect of the present invention, the semiconductor package may further include a plurality of switches, each disposed between each of the plurality of capacitors and the first semiconductor die or the second semiconductor die, wherein each of the plurality of capacitors may have a different capacitance.

According to yet another aspect of the present invention, a plurality of electrical paths may be disposed between the first semiconductor die and the second semiconductor die.

According to yet another aspect of the present invention, the semiconductor package may further include a capacitor chip in which the at least one capacitor are disposed as a plurality of capacitors on a single die, wherein each of the plurality of electrical paths may connect the first semiconductor die and the second semiconductor die through each of the plurality of capacitors included in the capacitor chip.

According to yet another aspect of the present invention, the at least one capacitor may be disposed on at least one of the plurality of electrical paths, the at least one of the plurality of electrical paths may be formed of a conductive wiring, and the conductive wiring direct current (DC)-couple the first semiconductor die and the second semiconductor die.

According to yet another aspect of the present invention, the at least one capacitor may be disposed on each of the plurality of electrical paths, and each of the at least one capacitor may have a different capacitance.

According to yet another aspect of the present invention, the first semiconductor die and the second semiconductor die may selectively transmit and receive an AC signal through an optimal path among the plurality of electrical paths, and the optimal path may be determined by a frequency of the AC signal and the capacitance.

According to yet another aspect of the present invention, the first semiconductor die and the second semiconductor die may include a serializer and a deserializer, respectively.

### BRIEF DESCRIPTION OF THE DRAWINGS

The above and other objects, features, and advantages of the present invention will become more apparent to those of ordinary skill in the art by describing exemplary embodiments thereof in detail with reference to the accompanying drawings, in which:

FIG. 1 is a top view of a semiconductor package according to one embodiment of the present disclosure;

FIG. 2 is a cross-sectional view of the semiconductor package of FIG. 1, taken along line II-II’;

FIG. 3 is a cross-sectional view of another embodiment of the semiconductor package of FIG. 1, taken along line II-II’;

FIG. 4 is a cross-sectional view of still another embodiment of the semiconductor package of FIG. 1, taken along line II-II’;

FIG. 5 is a top view of a semiconductor package including a plurality of capacitors connected in parallel according to another embodiment of the present disclosure;

FIG. 6 is a top view of a semiconductor package including capacitors connected in parallel and having different capacitances according to still another embodiment of the present disclosure;

FIG. 7 is a top view of a semiconductor package including a capacitor chip in which a plurality of capacitors according to yet another embodiment of the present disclosure are disposed;

FIG. 8 is a top view of a semiconductor package including an alternating current (AC)-coupled chip-to-chip communication line and a direct current (DC)-coupled chip-to-chip communication line according to yet another embodiment of the present disclosure; and

FIG. 9 is a top view of a semiconductor package including capacitors having different capacitances disposed on respective chip-to-chip communication lines according to yet another embodiment of the present disclosure.

### DETAILED DESCRIPTION OF EXEMPLARY EMBODIMENTS

Advantages and features of the present invention and implementation methods thereof will be clarified through the following embodiments described with reference to the accompanying drawings. However, the present invention is not limited to the embodiments described below and may be embodied with a variety of different modifications. The embodiments are merely provided to allow those skilled in the art to completely understand the scope of the present invention, and the present invention is defined only by the scope of the claims.

The figures, dimensions, ratios, angles, numbers, and the like disclosed in the drawings for describing the embodiments of the present invention are merely illustrative and are not limited to matters shown in the present invention. Further, in describing the present invention, detailed descriptions of well-known technologies will be omitted when it is determined that they may unnecessarily obscure the gist of the present invention. Terms such as “including,” “having,” and “composed of” used herein are intended to allow other elements to be added unless the terms are used with the term “only.” Any references to the singular may include the plural unless expressly stated otherwise.

Components are interpreted to include an ordinary error range even if not expressly stated.

Although the terms “first,” “second,” and the like may be used herein to describe various components, the components are not limited by the terms. These terms are used only to distinguish one component from another component. Therefore, a first component described below may be a second component within the technological scope of the present invention.

Unless otherwise indicated herein, throughout the specification, like reference numerals refer to like elements.

Features of various embodiments of the present invention may be partially or overall coupled to or combined with each other, and may be variously inter-operated with each other and driven technically as those skilled in the art can sufficiently understand. The embodiments of the present invention may be implemented independently from each other, or may be implemented together in co-dependent relationship.

The present invention will be described in detail with reference to the accompanying drawings.

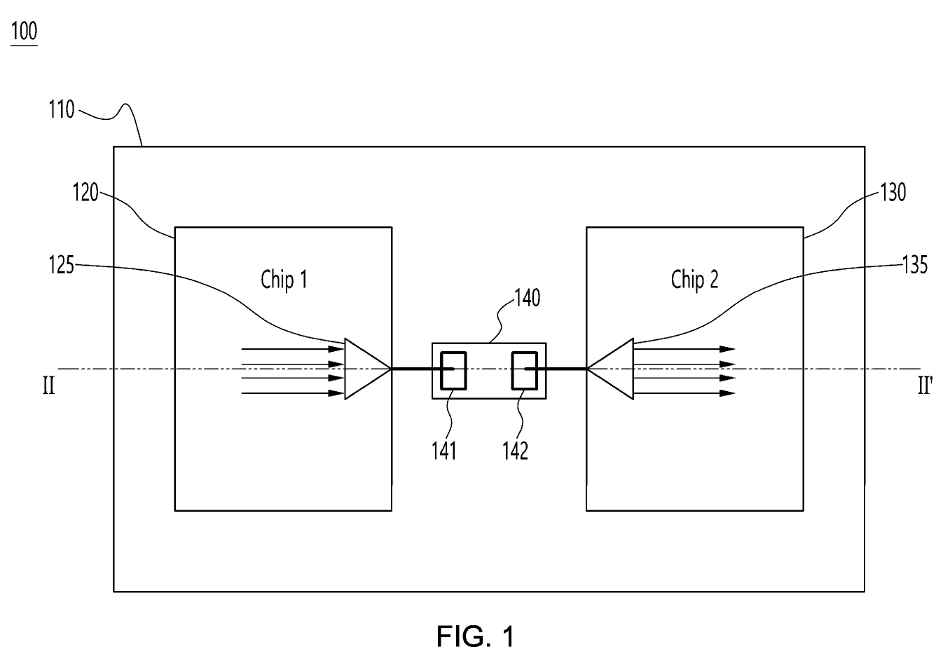

FIG. 1 is a top view of a semiconductor package according to one embodiment of the present disclosure.

Referring to FIG. 1, a semiconductor package 100 includes a package substrate 110, a first semiconductor die 120, a second semiconductor die 130, and a capacitor 140.

The semiconductor package 100 may be a device that protects the semiconductor dies and connects the semiconductor dies to an external circuit. Specifically, the semiconductor package 100 may be a device that integrates heterogeneous semiconductor dies into a single package. For example, the semiconductor package 100 may be a system-in-package (SiP).

The package substrate 110 is a substrate for a semiconductor package. Specifically, the package substrate 110 may connect at least one semiconductor die disposed on the package substrate 110 to external devices, or other chips or components. More specifically, the package substrate 110 may connect heterogeneous components disposed on the package substrate 110 to each other through bridge wirings, or connect the heterogeneous components to external devices through redistribution wirings.

The package substrate 110 may include a printed circuit board (PCB), an organic substrate, a ceramic substrate, a glass substrate, a silicon substrate, or a tape wiring substrate. For example, the package substrate 110 may be any one of a one-sided PCB, a double-sided PCB, and a multi-layer PCB.

The first semiconductor die 120 and the second semiconductor die 130 may be various electronic components, chips, or modules. For example, the first semiconductor die 120 and the second semiconductor die 130 may each include at least one of a central processing unit (CPU), a graphics processing unit (GPU), a neural processing unit (NPU), a memory, a communication module, and a radio frequency (RF) module. In some cases, the first semiconductor die 120 and the second semiconductor die 130 may be different electronic components. Specifically, the first semiconductor die 120 and the second semiconductor die 130 may be heterogeneous semiconductor dies fabricated through different manufacturing processes. Preferably, the first semiconductor die 120 and the second semiconductor die 130 may be chips, dies, or modules fabricated by microfabrication processes of different sizes. For example, the first semiconductor die 120 may be a semiconductor chip fabricated using a 14 nm process, and the second semiconductor die 130 may be a semiconductor chip fabricated using a 40 nm process. Accordingly, the semiconductor package 100 includes the first semiconductor die 120 and the second semiconductor die 130, which are heterogeneous, so that each of the semiconductor dies 120 and 130 may be efficiently disposed for specialized tasks. In addition, chips or modules fabricated using different processes or in different sizes may be disposed on one package substrate 110, and as a result, the integration density of chips disposed in the package substrate 110 can be enhanced and process efficiency and yield can also be improved.

Referring to FIG. 1, the first semiconductor die 120 and the second semiconductor die 130 may include at least one serializer 125 and at least one deserializer 135, respectively. The first semiconductor die 120 and the second semiconductor die 130 may perform chip-to-chip communication through the serializer 125 and the deserializer 135. Accordingly, the first semiconductor die 120 and the second semiconductor die 130 can perform chip-to-chip communication in a serial manner rather than a parallel manner, thereby simplifying a chip-to-chip communication line. As a result, in the semiconductor package 100, the complexity of connections between components can be reduced.

Referring to FIG. 1, the first semiconductor die 120 and the second semiconductor die 130 may be disposed on the package substrate 110. Specifically, the first semiconductor die 120 and the second semiconductor die 130 may be disposed to be spaced apart from each other on the package substrate 110. In some cases, the first semiconductor die 120 and the second semiconductor die 130 may be disposed adjacent to each other. In addition, the first semiconductor die 120 and the second semiconductor die 130 may be disposed in contact with each other. Thus, in the semiconductor package 100, miniaturization and integration density may be improved, and functions between the semiconductor dies 120 and 130 may be more efficiently integrated.

The semiconductor package 100 includes at least one capacitor 140. The capacitor 140 may be a variety of capacitors. For example, the capacitor 140 may be any one of a multi-layer ceramic capacitor (MLCC), a trench capacitor, a silicon capacitor, an embedded capacitor, and a thin-film capacitor. Preferably, the capacitor 140 may be a deep trench capacitor (DTC). Accordingly, the semiconductor package 100 can include a deep trench capacitor, which is advantageous for miniaturization and capable of securing capacitance in a vertical direction, thereby efficiently providing capacitances to semiconductor dies within a limited space.

The capacitor 140 may be disposed on at least one electrical path between the first semiconductor die 120 and the second semiconductor die 130. Specifically, the capacitor 140 may be disposed on a chip-to-chip communication line between the first semiconductor die 120 and the second semiconductor die 130. That is, the capacitor 140 may alternating current (AC)-couple the first semiconductor die 120 and the second semiconductor die 130. For example, as shown in FIG. 1, a first pad or bump 141 of the capacitor 140 may be connected to the first semiconductor die 120, and a second pad or bump 142 of the capacitor 140 may be connected to the second semiconductor die 130. Thus, the capacitor 140 may remove a direct current (DC) offset between the first semiconductor die 120 and the second semiconductor die 130 and improve compatibility between heterogeneous semiconductor dies by removing a DC component and allowing only high-frequency signals to pass in chip-to-chip communication between the first semiconductor die 120 and the second semiconductor die 130. In addition, the capacitor 140 may enhance electromagnetic interference (EMI) shielding performance and improve signal integrity by blocking common mode noise in chip-to-chip communication between the first semiconductor die 120 and the second semiconductor die 130.

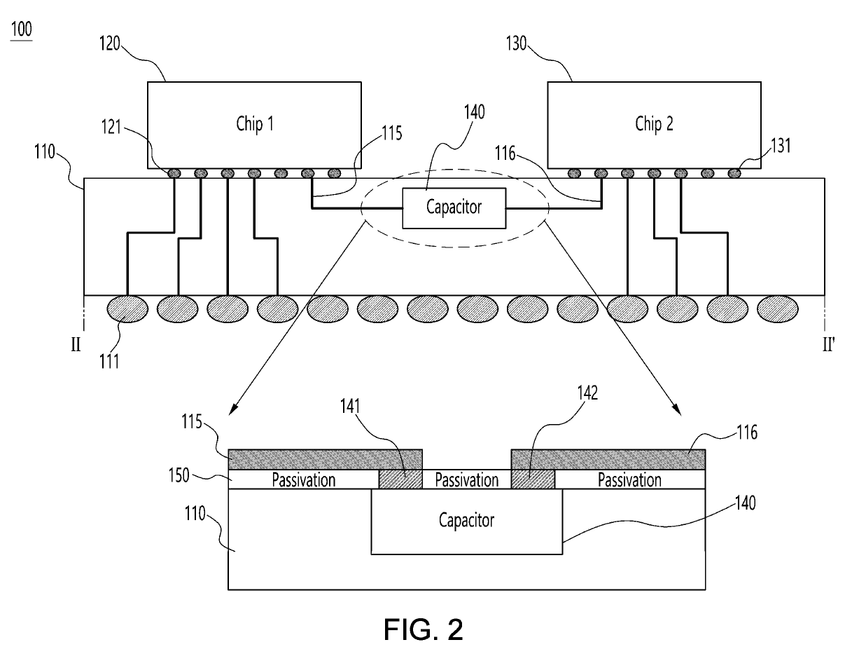

Referring to FIG. 1, the capacitor 140 may be disposed between the first semiconductor die 120 and the second semiconductor die 130. Specifically, the capacitor 140 may be disposed between the first semiconductor die 120 and the second semiconductor die 130 on the package substrate 110. In some cases, the capacitor 140 may be disposed in the package substrate 110, or may be disposed in an interposer (not shown) disposed between the package substrate 110 and the first and second semiconductor dies 120 and 130. For example, the capacitor 140 may be embedded in the package substrate 110, and may be disposed below the first semiconductor die 120 or the second semiconductor die 130. A detailed arrangement relationship between the capacitor 140 and the first and second semiconductor dies 120 and 130 will be described later with reference to FIGS. 2 to 4.

FIG. 2 is a cross-sectional view of the semiconductor package of FIG. 1, taken along line II-II’.

Referring to FIG. 2, the semiconductor package 100 may further include first connection bumps 111, second connection bumps or pads 121, third connection bumps or pads 131, and a passivation layer 150.

The first connection bump 111, the second connection bump or pad 121, and the third connection bump or pad 131 may include various types of bumps or pads. For example, each of the first connection bump 111, the second connection bump or pad 121, and the third connection bump or pad 131 may include any one of a solder ball, a flip-chip bump, a Cu bump, an Au bump, and a polymer bump. In addition, each of the second connection bump or pad 121 and the third connection bump or pad 131 may include one of a Cu pad, a W pad, a Ni/Au pad, and an Al pad. The first connection bumps 111 may be disposed below the package substrate 110. Specifically, the first connection bump 111 may be disposed on a lower surface of the pad disposed on a lower surface of the package substrate 110.

The first connection bumps 111 may connect the package substrate 110 to an external device. For example, the first connection bumps 111 may connect the package substrate 110 to a PCB disposed below the package substrate 110.

The second connection bumps or pads 121 may be disposed below the first semiconductor die 120. Specifically, the second connection bumps or pads 121 may be disposed between the first semiconductor die 120 and the package substrate 110. More specifically, the second connection bump or pad 121 may be disposed between the pad disposed on a lower surface of the first semiconductor die 120 and the pad disposed on an upper surface of the package substrate 110.

The second connection bump or pad 121 may connect the first semiconductor die 120 and the package substrate 110. That is, the first semiconductor die 120 may be connected to an external device through the second connection bumps or pads 121 and the redistribution wiring of the package substrate 110.

The third connection bumps or pads 131 may be disposed below the second semiconductor die 130. Specifically, the third connection bumps or pads 131 may be disposed between the second semiconductor die 130 and the package substrate 110. More specifically, the third connection bump or pad 131 may be disposed between the pad disposed on a lower surface of the second semiconductor die 130 and the pad disposed on the upper surface of the package substrate 110.

The third connection bumps or pads 131 may connect the second semiconductor die 130 and the package substrate 110. That is, the second semiconductor die 130 may be connected to an external device through the third connection bumps or pads 131 and the redistribution wiring of the package substrate 110.

Referring to FIG. 2, the capacitor 140 includes the first pad or bump 141 and the second pad or bump 142. The first pad or bump 141 may be connected to one electrode of the capacitor 140, and the second pad or bump 142 may be connected to the other electrode of the capacitor 140. As shown in FIG. 2, the first pad or bump 141 and the second pad or bump 142 may be disposed on an upper surface of the capacitor 140. In some cases, the first pad or bump 141 and the second pad or bump 142 may be disposed on a side or lower surface of the capacitor 140.

The capacitor 140 may be disposed in the package substrate 110. Specifically, the capacitor 140 may be disposed in a groove formed in the upper surface of the package substrate 110. In some cases, the capacitor 140 may be embedded in the package substrate 110.

The capacitor 140 may be connected to the first semiconductor die 120 and the second semiconductor die 130 through a first bridge wiring 115 and a second bridge wiring 116. Specifically, the first pad or bump 141 of the capacitor 140 may be connected to the first semiconductor die 120 through the first bridge wiring 115, and the second pad or bump 142 of the capacitor 140 may be connected to the second semiconductor die 130 through the second bridge wiring 116.

Referring to FIG. 2, the first bridge wiring 115 and the second bridge wiring 116 may be disposed above the passivation layer 150. In some cases, the first bridge wiring 115 and the second bridge wiring 116 may be disposed between a plurality of passivation layers 150 and may also be disposed on the upper surface of the package substrate 110. When the capacitor 140 is embedded in the package substrate 110, the first bridge wiring 115 and the second bridge wiring 116 may also be disposed in the package substrate 110.

The passivation layer 150 may be disposed on the package substrate 110. Specifically, as shown in FIG. 2, the passivation layer 150 may be disposed on the upper surface of the package substrate 110 and the upper surface of the capacitor 140.

The passivation layer 150 may include low-dielectric constant and low-loss tangent materials. Specifically, the passivation layer 150 may include various low-dielectric constant materials depending on the package substrate 110. For example, when the package substrate 110 is a silicon substrate, the passivation layer 150 may include at least one of SiO₂, Si₃N₄, SiCN, and SiCOH. When the package substrate 110 is an organic substrate, the passivation layer 150 may include at least one polymer-based low-dielectric constant material such as benzocyclobutene (BCB), polyimide, or cyclic olefin copolymer (COC). When the package substrate 110 is a glass substrate, the passivation layer 150 may include at least one of a polymer material and a porous material that are stable and have a coefficient of thermal expansion similar to that of the glass substrate. Accordingly, the passivation layer 150 may reduce transmission loss in wirings in the package substrate 110 by including low-dielectric constant and low-loss tangent materials depending on the package substrate 110.

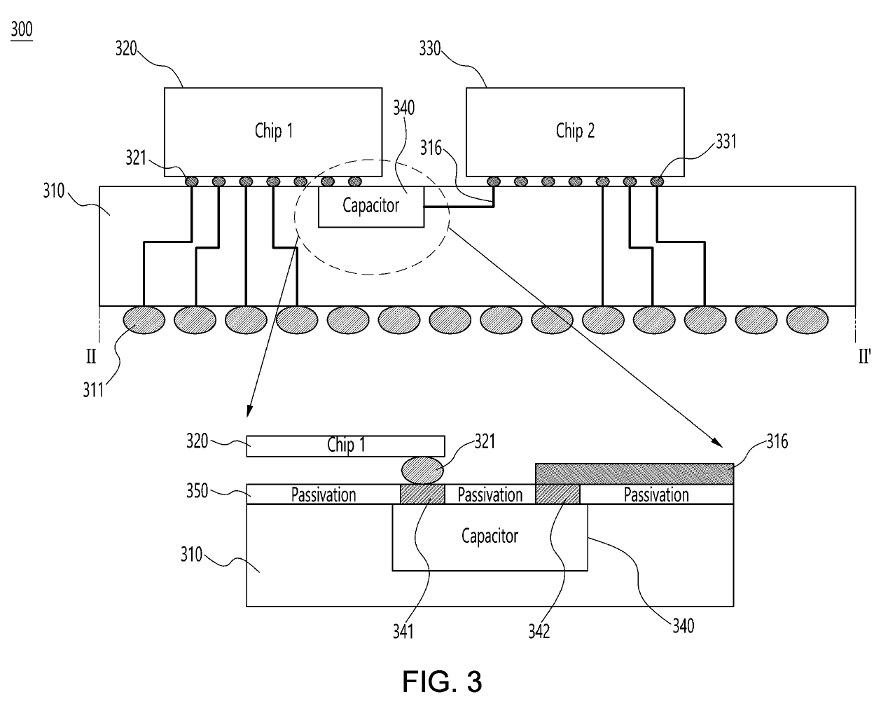

FIG. 3 is a cross-sectional view of another embodiment of the semiconductor package of FIG. 1, taken along line II-II’.

Referring to FIG. 3, a semiconductor package 300 according to the present embodiment may be configured such that at least a portion of a capacitor 340 is disposed below a first semiconductor die 320 based on the configuration of the semiconductor package 100 of FIG. 1. Accordingly, redundant descriptions of configurations that are substantially identical to those of the semiconductor package 100 of FIGS. 1 and 2 will be omitted.

The capacitor 340 may be disposed below the first semiconductor die 320 or below a second semiconductor die 330. Specifically, at least a portion of the capacitor 340 may be disposed to overlap the first semiconductor die 320 or the second semiconductor die 330 at a position below the first semiconductor die 320 or the second semiconductor die 330. For example, as shown in FIG. 3, the capacitor 340 may be disposed in a partial region below the first semiconductor die 320. In some cases, the capacitor 340 may be disposed in a partial region below the second semiconductor die 330. When the first semiconductor die 320 and the second semiconductor die 330 are disposed in close contact with each other, the capacitor 340 may also be disposed in a partial region below both the first semiconductor die 320 and the second semiconductor die 330.

Referring to FIG. 3, the capacitor 340 may be directly connected to the first semiconductor die 320. Specifically, a first pad or bump 341 of the capacitor 340 may be directly connected to a second connection bump or pad 321 disposed below the first semiconductor die 320. In some cases, a second pad or bump 342 of the capacitor 340 may be directly connected to a third connection bump or pad 331 disposed below the second semiconductor die 330. Accordingly, the semiconductor package 300 may exclude at least one of a first bridge wiring (not shown) and a second bridge wiring 316.

The semiconductor package 300 according to the present embodiment may include the capacitor 340 disposed below the first semiconductor die 320 or the second semiconductor die 330, which allows the first semiconductor die 320 and the second semiconductor die 330 to be disposed in close contact with each other. Thus, the integration density of the semiconductor package 300 may be improved. Furthermore, the semiconductor package 300 may reduce equivalent series inductance (ESL) and equivalent series resistance (ESR) by including a reduced number of bridge wirings.

In the semiconductor package 300 according to the present embodiment, the first bridge wiring and contact holes may be omitted by including the capacitor 340 that is directly connected below the first semiconductor die 320 or the second semiconductor die 330. Accordingly, in the semiconductor package 300, impedance discontinuities can be reduced and signal integrity can be improved by omitting a contact portion between the second connection bump or pad 321 and the first bridge wiring, a contact portion between vertical and horizontal wirings of the first bridge wiring, and a contact portion between the first bridge wiring and the first pad or bump 341.

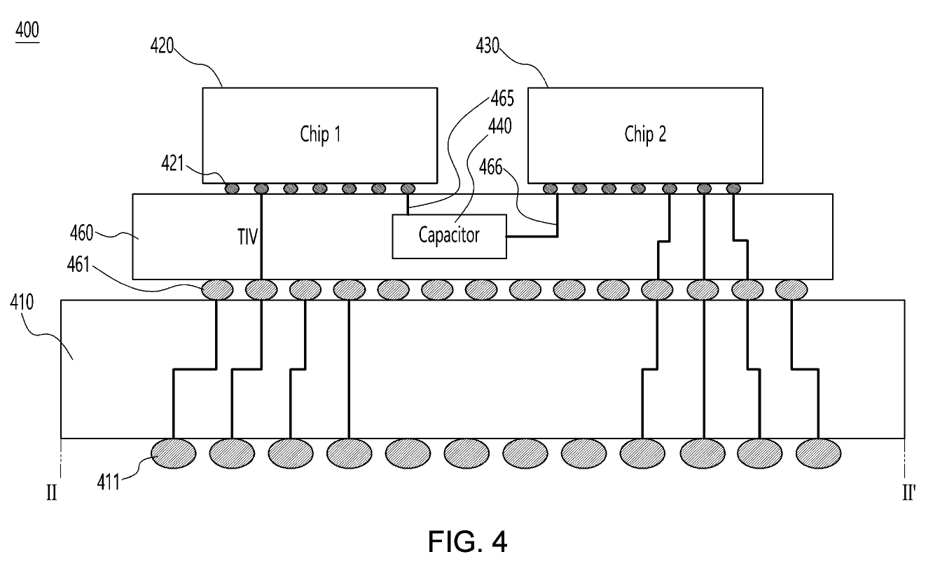

FIG. 4 is a cross-sectional view of still another embodiment of the semiconductor package of FIG. 1, taken along line II-II’.

Referring to FIG. 4, a semiconductor package 400 according to the present embodiment may further include an interposer 460 and may be configured such that a capacitor 440 is disposed in the interposer 460 based on the configuration of the semiconductor package 100 of FIG. 1. Accordingly, redundant descriptions of configurations that are substantially identical to those of the semiconductor package 100 of FIG. 1 will be omitted.

The interposer 460 may include a semiconductor material. For example, the interposer 460 may include semiconductor elements such as silicon and germanium, or compound semiconductors such as SiC, GaAs, InAs, and InP. Preferably, the interposer 460 may be a silicon interposer. According to various embodiments of the present invention, the interposer 460 may include an organic material. For example, the interposer 460 may be an organic interposer that includes materials such as polyimide, bismaleimide triazine (BT) resin, and Ajinomoto build-up film (ABF).

The interposer 460 may be disposed below a first semiconductor die 420 and a second semiconductor die 430. Specifically, as shown in FIG. 4, the interposer 460 may be disposed between the first and second semiconductor dies 420 and 430 and a package substrate 410.

The interposer 460 may connect the first and second semiconductor dies 420 and 430 to the package substrate 410. Specifically, the first and second semiconductor dies 420 and 430 may be connected to the package substrate 410 through through-interposer vias (TIVs) disposed in the interposer 460 and fourth connection bumps or pads 461 disposed below the interposer 460. In some cases, the interposer 460 may connect the first and second semiconductor dies 420 and 430 to the package substrate 410 through the TIVs or redistribution wirings.

The interposer 460 may connect the first semiconductor die 420 and the second semiconductor die 430. Specifically, the first semiconductor die 420 and the second semiconductor die 430 may be connected to each other through bridge wirings 465 and 466 disposed in the interposer 460. Preferably, as shown in FIG. 4, the first semiconductor die 420 and the second semiconductor die 430 may be connected to each other through the capacitor 440 and the bridge wirings 465 and 466 disposed in the interposer 460.

The capacitor 440 may be disposed in the interposer 460. Specifically, the capacitor 440 may be embedded in the interposer 460. In some cases, the capacitor 440 may be disposed in a groove formed in an upper surface of the interposer 460.

The arrangement relationship between the capacitor 440 and the first and second semiconductor dies 420 and 430 may be substantially the same as the arrangement relationship between the capacitor 340 and the first and second semiconductor dies 320 and 330 of FIG. 3. That is, the capacitor 440 may be disposed below the first semiconductor die 420 or below the second semiconductor die 430. In this case, the capacitor 440 may be disposed to overlap the first semiconductor die 420 or the second semiconductor die 430 at a position therebelow.

Referring to FIG. 4, the capacitor 440 may be connected to the first semiconductor die 420 through a first bridge wiring 465 and connected to the second semiconductor die 430 through a second bridge wiring 466. When the capacitor 440 is disposed below the first semiconductor die 420, the first bridge wiring 465 may be a vertical via. In some cases, the second bridge wiring 466 may be a vertical via, or both the first bridge wiring 465 and the second bridge wiring 466 may be vertical vias.

When the first bridge wiring 465 and the second bridge wiring 466 are vertical vias, the first bridge wiring 465 and the second bridge wiring 466 may be formed by the same process as the TIVs of the interposer 460. Accordingly, in the manufacturing process of the interposer 460, additional wiring processes for forming horizontal wirings and bridge wirings may be omitted, thereby reducing wiring complexity within the interposer 460.

The semiconductor package 400 according to the present embodiment may include the capacitor 440 connected to the semiconductor dies 420 and 430 through the vertical via-type bridge wirings 465 and 466 in the interposer 460, thereby allowing the bridge wirings 465 and 466 to be formed using the same process as the TIVs of the interposer 460. Accordingly, since the TIVs and the bridge wirings 465 and 466 are simultaneously formed in a single process without additional wiring processes, the manufacturing process can be simplified, thereby reducing time and costs. In addition, the interposer 460 can reduce wiring complexity and significantly increase wiring density by connecting the embedded capacitor 440 using only the vertical vias.

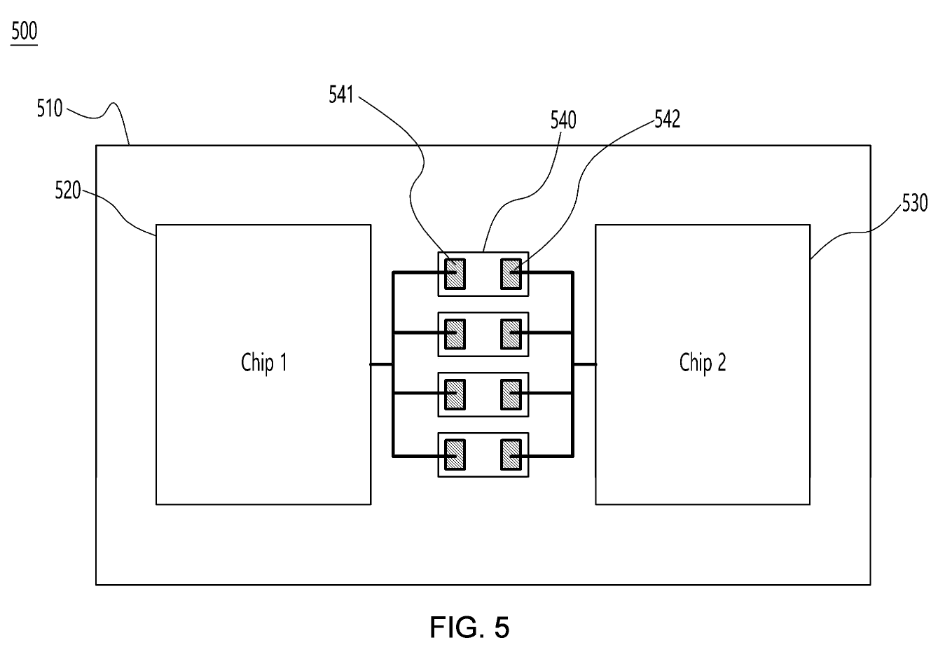

FIG. 5 is a top view of a semiconductor package including a plurality of capacitors connected in parallel according to another embodiment of the present disclosure.

Referring to FIG. 5, a semiconductor package 500 according to the present embodiment may further include at least one capacitor 540 and may be configured such that a plurality of capacitors 540 are connected in parallel with each other based on the configuration of the semiconductor package 100 of FIG. 1. Accordingly, redundant descriptions of configurations that are substantially identical to those of the semiconductor package 100 of FIG. 1 will be omitted.

The plurality of capacitors 540 may be connected to each other in parallel. Specifically, as shown in FIG. 5, first pads or bumps 541 of the plurality of capacitors 540 may be connected to each other, and second pads or bumps 542 of the plurality of capacitors 540 may be connected to each other. In FIG. 5, it is illustrated that, on a package substrate 510, the first pads or bumps 541 are connected to each other and the second pads or bumps 542 are connected to each other. However, according to various embodiments of the present invention, the first pads or bumps 541 may be connected to each other in a first semiconductor die 520, and the second pads or bumps 542 may be connected to each other in a second semiconductor die 530.

Each of the plurality of capacitors 540 may be substantially the same as the capacitor 140 of FIG. 1. Specifically, each of the plurality of capacitors 540 may have the same type, size, and capacitance as the capacitor 140 of FIG. 1.

The plurality of capacitors 540 may be disposed in the package substrate 510. According to various embodiments of the present invention, the plurality of capacitors 540 may be disposed in an interposer (not shown) disposed between the first and second semiconductor dies 520 and 530 and the package substrate 510.

The plurality of capacitors 540 connected in parallel may be disposed on an electrical path between the first semiconductor die 520 and the second semiconductor die 530. Specifically, the plurality of capacitors 540 connected in parallel may be disposed on one chip-to-chip communication line between the first semiconductor die 520 and the second semiconductor die 530.

The number of the plurality of capacitors 540 connected in parallel may be determined based on the frequency of a chip-to-chip communication signal between the first semiconductor die 520 and the second semiconductor die 530. Specifically, the number of the plurality of capacitors 540 connected in parallel may be determined such that an optimal equivalent capacitance is achieved according to the frequency of the chip-to-chip communication signal between the first semiconductor die 520 and the second semiconductor die 530.

According to various embodiments of the present invention, a plurality of switches (not shown) may each be disposed between each of the plurality of capacitors 540 connected in parallel and the first semiconductor die 520, or the second semiconductor die 530. For example, each switch may be disposed between the first semiconductor die 520 and the first pad or bump 541 of each of the plurality of capacitors 540 connected in parallel. The first semiconductor die 520 and the second semiconductor die 530 may control ON/OFF of each of the plurality of switches. Accordingly, the first semiconductor die 520 and the second semiconductor die 530 can adjust the equivalent capacitance of the chip-to-chip communication line in real time by controlling the switches in real time based on the frequency of the transmission signal. Accordingly, the first semiconductor die 520 and the second semiconductor die 530 can minimize signal distortion according to a frequency band of the chip-to-chip communication signal and maintain uniform signal quality over a wide bandwidth by adjusting the equivalent capacitance of the chip-to-chip communication line in real time according to the frequency of the transmission signal.

In the semiconductor package 500 according to the present embodiment, the equivalent capacitance may be precisely implemented according to the frequency of the chip-to-chip communication signal by including a plurality of AC-coupling capacitors connected in parallel. In addition, even when errors occur in the capacitances of the capacitors due to manufacturing tolerances, a target capacitance can be more closely approximated through parallel combination.

Further, in the semiconductor package 500 according to the present embodiment, the equivalent capacitance of the chip-to-chip communication line may be adjusted in real time by including the first semiconductor die 520 and the second semiconductor die 530, which control the connection of each of the capacitors connected in parallel using switches. Accordingly, the semiconductor package 500 can minimize signal distortion according to the frequency band of the chip-to-chip communication signal and maintain uniform signal quality over a wide bandwidth.

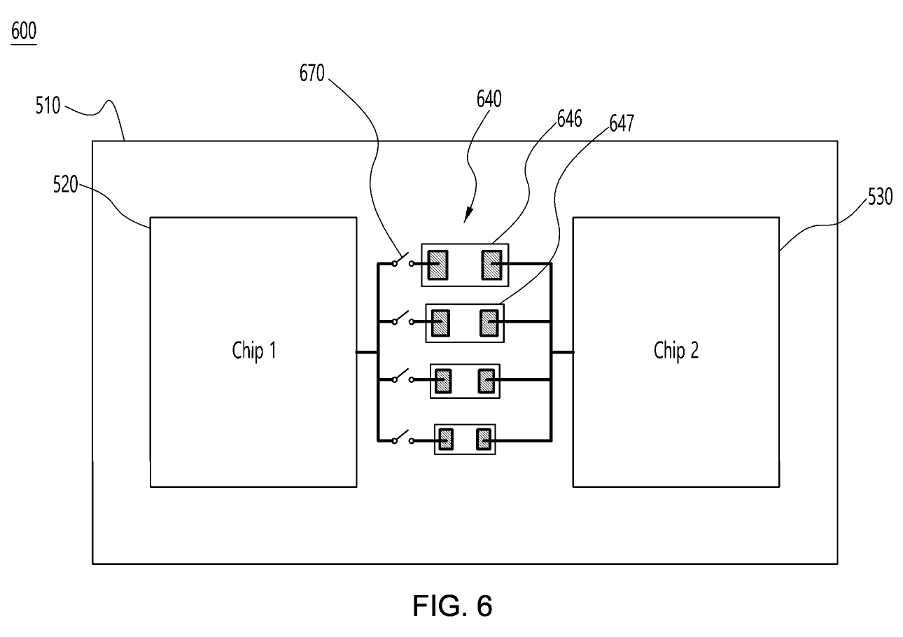

FIG. 6 is a top view of a semiconductor package including capacitors connected in parallel and having different capacitances according to still another embodiment of the present disclosure.

Referring to FIG. 6, a semiconductor package 600 according to the present embodiment may include a plurality of capacitors 640 connected in parallel and having different capacitances and may further include switches 670 based on the configuration of the semiconductor package 500 of FIG. 5. Accordingly, redundant descriptions of configurations that are substantially identical to those of the semiconductor package 500 of FIG. 5 will be omitted.

The plurality of capacitors 640 may be capacitors of substantially the same type as the capacitor 140 of FIG. 1. The plurality of capacitors 640 connected in parallel may have different capacitances. For example, a first capacitor 646 may have a larger capacitance than a second capacitor 647.

The plurality of capacitors 640 may be disposed in the package substrate 510. According to various embodiments of the present invention, the plurality of capacitors 640 may be disposed in the interposer (not shown) disposed between the first and second semiconductor dies 520 and 530 and the package substrate 510.

Referring to FIG. 6, a plurality of switches 670 may each be disposed between each of the plurality of capacitors 640 connected in parallel and the first semiconductor die 520, or the second semiconductor die 530.

The first semiconductor die 520 and the second semiconductor die 530 may control ON/OFF of each of the plurality of switches 670. Accordingly, the first semiconductor die 520 and the second semiconductor die 530 can control the switches 670 in real time based on the frequency of the transmission signal, thereby adjusting the equivalent capacitance of the chip-to-chip communication line in real time. Accordingly, the first semiconductor die 520 and the second semiconductor die 530 can minimize signal distortion according to a frequency band of the chip-to-chip communication signal and maintain uniform signal quality over a wide bandwidth by adjusting the equivalent capacitance of the chip-to-chip communication line in real time according to the frequency of the transmission signal.

In the semiconductor package 600 according to the present embodiment, the equivalent capacitance may be more finely and accurately adjusted by including AC-coupling capacitors that are connected in parallel and have different capacitances.

Further, in the semiconductor package 600 according to the present embodiment, the equivalent capacitance of the chip-to-chip communication line may be more finely adjusted in real time by including the first semiconductor die 520 and the second semiconductor die 530, which control the connection of each of the capacitors connected in parallel using switches. Accordingly, the semiconductor package 600 can minimize signal distortion according to the frequency band of the chip-to-chip communication signal and maintain uniform signal quality over a wide bandwidth.

Further, in the semiconductor package 600 according to the present embodiment, each capacitor may operate with optimal signal transmission characteristics over various frequency bands by including AC-coupling capacitors that are connected in parallel and have different capacitances. For example, in the semiconductor package 600, appropriate capacitor paths may be utilized across all frequency bands by including a high-capacitance capacitor for low-frequency signals, a mid-capacitance capacitor for mid-frequency signals, and a low-capacitance capacitor for high-frequency signals, thereby maintaining signal quality.

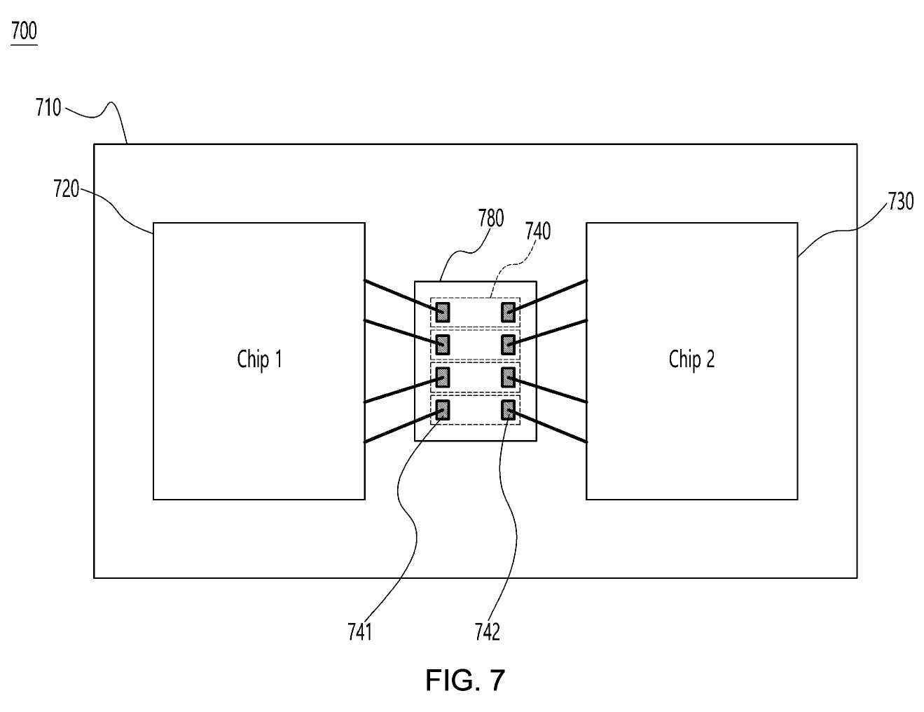

FIG. 7 is a top view of a semiconductor package including a capacitor chip in which a plurality of capacitors according to yet another embodiment of the present disclosure are disposed.

Referring to FIG. 7, a semiconductor package 700 according to the present embodiment further includes a capacitor chip 780 in which a plurality of capacitors 740 are disposed and may be configured such that a plurality of chip-to-chip communication lines are disposed based on the configuration of the semiconductor package 100 of FIG. 1.

The capacitor chip 780 may include the plurality of capacitors 740. Specifically, the capacitor chip 780 may include the plurality of capacitors 740 disposed a single die.

The capacitor chip 780 may be disposed in a package substrate 710. Specifically, the capacitor chip 780 may be disposed in a groove formed in an upper surface of the package substrate 710, or may be embedded in the package substrate 710. According to various embodiments of the present invention, the capacitor chip 780 may be disposed in an interposer (not shown) disposed between first and second semiconductor dies 720 and 730 and the package substrate 710.

Each of the plurality of capacitors 740 may be a capacitor that is substantially the same as the capacitor 140 of FIG. 1. Specifically, each of the plurality of capacitors 740 may have the same type, size, and capacitance as the capacitor 140 of FIG. 1.

The plurality of capacitors 740 may be disposed adjacent to each other in the capacitor chip 780. Specifically, as shown in FIG. 7, the plurality of capacitors 740 may be disposed adjacent to each other in one direction in the capacitor chip 780. For example, a first pad or bump 741 of each of the plurality of capacitors 740 may be disposed to face the first semiconductor die 720, and a second pad or bump 742 of each of the plurality of capacitors 740 may be disposed to face the second semiconductor die 730.

Between the first semiconductor die 720 and the second semiconductor die 730, a plurality of electrical paths may be disposed. The plurality of capacitors 740 may be disposed on the plurality of electrical paths, respectively, For example, as shown in FIG. 7, the capacitors 740 may be disposed on the plurality of electrical paths, respectively.

According to various embodiments of the present invention, at least one switch (not shown) may be disposed on each of the plurality of electrical paths disposed between the first semiconductor die 720 and the second semiconductor die 730. Specifically, the switch may be disposed between each of the plurality of capacitors 740 and the first semiconductor die 720 or the second semiconductor die 730. For example, the switch may be disposed between the first pad or bump 741 of each of the plurality of capacitors 740 and the first semiconductor die 720.

In some cases, a plurality of switches may be disposed in the first semiconductor die 720 or the second semiconductor die 730. Specifically, the plurality of switches (not shown) may be disposed in the first semiconductor die 720 or the second semiconductor die 730, on the respective electrical paths between the first semiconductor die 720 and the second semiconductor die 730.

The first semiconductor die 720 and the second semiconductor die 730 may control ON/OFF of each of the plurality of switches. Accordingly, the first semiconductor die 720 and the second semiconductor die 730 can select a chip-to-chip communication line with a capacitance optimized for the frequency of a transmission signal by controlling the switches in real time based on the frequency of the transmission signal. Accordingly, the first semiconductor die 720 and the second semiconductor die 730 can minimize signal distortion based on a frequency band of the chip-to-chip communication signal and maintain uniform signal quality over a wide bandwidth by switching the chip-to-chip communication line to an electrical path with an optimal capacitance in real time. In the semiconductor package 700 according to the present embodiment, the plurality of capacitors 740 may be integrated into one capacitor chip 780, thereby minimizing a spacing between the plurality of capacitors 740. Accordingly, in the semiconductor package 700, a larger number of capacitors 740 can be integrated in the same area, thereby achieving higher capacitance within the same space and improving area efficiency of the package. In addition, by including the plurality of capacitors 740 in one capacitor chip 780 and connecting a different electrical path to each capacitor 740, various electrical paths can be selectively used for signal transmission based on the characteristics of the signal. In particular, when each capacitor 740 has a different capacitance, one capacitor chip 780 alone can provide various electrical paths, thereby enhancing the integration density of the semiconductor package 700.

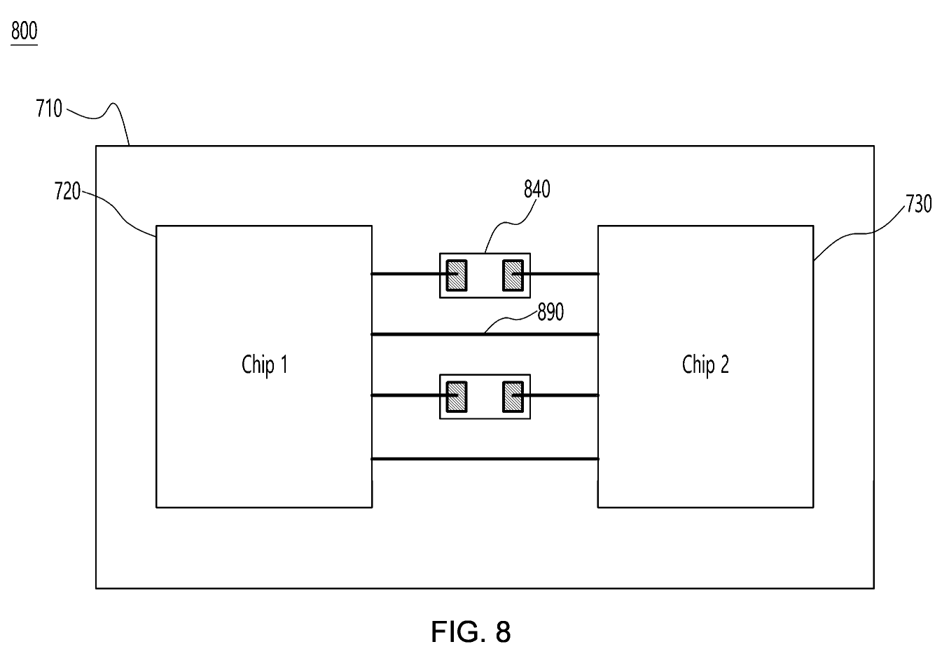

FIG. 8 is a top view of a semiconductor package including an AC-coupled chip-to-chip communication line and a DC-coupled chip-to-chip communication line according to yet another embodiment of the present disclosure.

Referring to FIG. 8, a semiconductor package 800 according to the present embodiment may further include a conductive wiring 890 and may be configured such that a plurality of chip-to-chip communication lines are disposed based on the configuration of the semiconductor package 100 of FIG. 1. Accordingly, redundant descriptions of configurations that are substantially identical to those of the semiconductor package 100 of FIG. 1 will be omitted.

A plurality of electrical paths may be disposed between the first semiconductor die 720 and the second semiconductor die 730. Specifically, as shown in FIG. 8, at least one chip-to-chip communication line on which a capacitor 840 is disposed and at least one chip-to-chip communication line composed of the conductive wiring 890 may be disposed between the first semiconductor die 720 and the second semiconductor die 730. That is, at least one AC communication line in which the capacitor 840 is AC-coupled and at least one DC communication line in which the conductive wiring 890 is DC-coupled may be disposed between the first semiconductor die 720 and the second semiconductor die 730.

The capacitor 840 may be a capacitor that is substantially the same as the capacitor 140 of FIG. 1. Specifically, the capacitor 840 may have the same type, size, and capacitance as the capacitor 140 of FIG. 1.

The capacitor 840 may be disposed in the package substrate 710. According to various embodiments of the present invention, the capacitor 840 may be disposed in the interposer (not shown) disposed between the first and second semiconductor dies 720 and 730 and the package substrate 710.

The conductive wiring 890 may be a bridge wiring disposed on the package substrate 710. Specifically, the conductive wiring 890 may be a metal wiring disposed on the package substrate 710. In some cases, the conductive wiring 890 may be a metal wiring disposed in the package substrate 710. According to various embodiments of the present invention, the conductive wiring 890 may be disposed in the interposer (not shown) disposed between the first and second semiconductor dies 720 and 730 and the package substrate 710.

The first semiconductor die 720 and the second semiconductor die 730 may selectively use the communication line in which the capacitor 840 is disposed and the communication line composed of the conductive wiring 890. Specifically, the first semiconductor die 720 and the second semiconductor die 730 may select an optimal communication line based on the type and frequency of a transmission signal and transmit the signal through the optimal communication line. The optimal communication line may be determined based on the type and frequency of the transmission signal. For example, the first semiconductor die 720 and the second semiconductor die 730 may transmit high-frequency signals through the communication line on which the capacitor 840 is disposed, and may transmit low-frequency or DC signals through the communication line composed of the conductive wiring 890. That is, the first semiconductor die 720 and the second semiconductor die 730 may transmit relatively high-frequency and high-speed data signals, such as those used in Peripheral Component Interconnect express (PCIe), Universal Chiplet Interconnect express (UCIe), Universal Serial Bus (USB) 3.x, USB 4.0, Double Data Rate 4 (DDR4), DDR5, or Mobile Industry Processor Interface Camera Serial Interface/Display Serial Interface (MIPI CSI/DSI), through the communication line in which the capacitor 840 is disposed, may transmit at least one of relatively low-frequency and low-speed control and status information signals-such as Inter-Integrated Circuit (I2C), Serial Peripheral Interface (SPI), General-Purpose Input/Output (GPIO), or Universal Asynchronous Receiver Transmitter (UART) signals-clock signals, serial data signals, operation setting signals, interrupt signals, power, ground, and DC signals through the communication line composed of the conductive wiring 890. In some cases, the first semiconductor die 720 and the second semiconductor die 730 may transmit AC signals through the communication line in which the capacitor 840 is disposed, and may transmit DC signals through the communication line composed of the conductive wiring 890.

In the semiconductor package 800 according to the present embodiment, by including the AC communication line in which the capacitor 840 is AC-coupled and the DC communication line in which the conductive wiring 890 is DC-coupled, the optimal communication line can be selected according to the frequency of the transmission signal and used for transmission. Accordingly, the semiconductor package 800 can transmit high-quality signals over a wide bandwidth without signal distortion and loss.

Further, the semiconductor package 800 according to the present embodiment may improve the compatibility of semiconductor dies with different frequency characteristics by including channels for various signal bands.

Further, the semiconductor package 800 according to the present embodiment may ensure compatibility without requiring redesign even when adding new chips or replacing existing chips in the package by including communication lines that support multiple bands. Thus, the system scalability of the semiconductor package 800 may be increased.

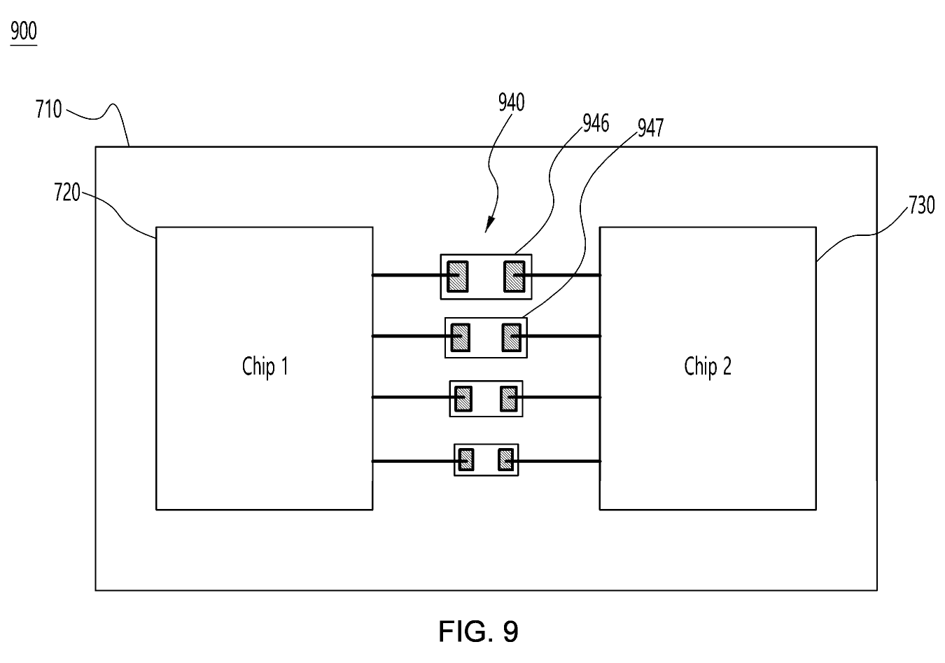

FIG. 9 is a top view of a semiconductor package including capacitors having different capacitances disposed on respective chip-to-chip communication lines according to yet another embodiment of the present disclosure.

Referring to FIG. 9, a semiconductor package 900 according to the present embodiment may be configured such that capacitors with different capacitances are disposed on a plurality of chip-to-chip communication lines based on the configuration of the semiconductor package 800 of FIG. 8. Accordingly, redundant descriptions of configurations that are substantially identical to those of the semiconductor package 100 of FIG. 1 and the semiconductor package 800 of FIG. 8 will be omitted.

Capacitors 940 may be respectively disposed on a plurality of electrical paths between the first semiconductor die 720 and the second semiconductor die 730. Specifically, as shown in FIG. 9, the capacitors 940 with different capacitances may be respectively disposed on the plurality of chip-to-chip communication lines between the first semiconductor die 720 and the second semiconductor die 730. For example, a capacitance of a first capacitor 946 may be greater than a capacitance of a second capacitor 947. According to various embodiments of the present invention, a communication line in which a conductive wiring (not shown) is DC-coupled may also be disposed between the first semiconductor die 720 and the second semiconductor die 730.

According to various embodiments of the present invention, a plurality of capacitors 940 with different capacitances may be disposed in a single capacitor chip (not shown). The capacitor chip may include the plurality of capacitors 940 with different capacitances disposed a single die. For example, the first capacitor 946 and the second capacitor 947 may be disposed in a single capacitor chip. The capacitor chip (not shown) may be disposed in substantially the same position as the capacitor chip 780 of FIG. 7. That is, the capacitor chip 780 shown in FIG. 7 may include the plurality of capacitors 940 with different capacitances shown in FIG. 9, and may be disposed in the semiconductor package 900.

As the plurality of capacitors 940 with different capacitances are integrated into one capacitor chip (not shown), a spacing between the plurality of capacitors 940 may be minimized. Accordingly, in the semiconductor package 900, a larger number of capacitors 940 can be integrated in the same area, thereby achieving higher capacitance within the same space and improving area efficiency of the package. In addition, since one capacitor chip includes the plurality of capacitors 940 each connected to a different electrical path, the first semiconductor die 720 and the second semiconductor die 730 can transmit chip-to-chip communication signals through various electrical paths depending on the characteristics of the signals. In particular, since each of the plurality of capacitors 940 has a different capacitance, even one capacitor chip can provide various electrical paths, thereby enhancing the integration density of the semiconductor package 900.

The first and second semiconductor dies 720 and 730 may selectively use the chip-to-chip communication lines on which the capacitors 940 with different capacitances are disposed. Specifically, the first semiconductor die 720 and the second semiconductor die 730 may selectively transmit signals through the chip-to-chip communication line, in which the capacitor 940 with an optimal capacitance is disposed, depending on the type and frequency of the transmission signal. For example, when the first and second semiconductor dies 720 and 730 transmit high-frequency signals, the first and second semiconductor dies 720 and 730 may select the communication line with an appropriate capacitance from among the communication lines with relatively small capacitances and transmit the signals through the selected communication line.

According to various embodiments of the present invention, as the communication line in which the conductive wiring (not shown) is DC-coupled is disposed between the first semiconductor die 720 and the second semiconductor die 730, the first semiconductor die 720 and the second semiconductor die 730 may also transmit DC signals and some low-frequency signals through the conductive wiring. That is, the first semiconductor die 720 and the second semiconductor die 730 may transmit data signals with relatively high frequency and speed, such as those used in PCIe, UCIe, USB 3.x, USB 4.0, DDR4, DDR5, or MIPI CSI/DSI, through the chip-to-chip communication lines with relatively low capacitance, may transmit signals with relatively moderate frequency and speed, such as SATA, Ethernet, Inter-IC Sound (I2S), or embedded Multi-Media Controller (eMMC)/Universal Flash Storage (UFS) signals, through the chip-to-chip communication lines with moderate capacitance, such as those including the second capacitor 947, and may transmit signals with relatively low frequency and speed, such as I2C signals, SPI signals, GPIO signals, or UART signals, through chip-to-chip communication lines with relatively high capacitance, such as those including the first capacitor 946.

According to various embodiments of the present invention, since the communication channel in which the conductive wiring (not shown) is DC-coupled is disposed between the first semiconductor die 720 and the second semiconductor die 730, the first semiconductor die 720 and the second semiconductor die 730 may also transmit signals with relatively low frequency and speed, such as I2C, SPI, GPIO, or UART signals, as well as DC signals, through the conductive wiring.

In the semiconductor package 900 according to the present embodiment, by including the communication lines in which the capacitors 940 with different capacitances are disposed, the semiconductor dies 720 and 730 disposed in the semiconductor package 900 may transmit and receive signals across various frequency bands, ranging from low frequencies to high frequencies.

Further, the semiconductor package 900 may minimize transmission signal bandwidth loss and support multi-band communication by including the communication lines with a capacitance optimized for each frequency band of the transmission signal. That is, the semiconductor dies 720 and 730 disposed in the semiconductor package 900 may simultaneously transmit and receive low-frequency data and high-frequency high-speed signals.

Further, the semiconductor package 900 according to the present embodiment may improve the compatibility of the semiconductor dies 720 and 730 with different frequency characteristics by including channels for various signal bands.

Further, the semiconductor package 900 according to the present embodiment may increase design flexibility and system scalability by including the communication lines that support multiple frequency bands. For example, when adding a new chip or replacing an existing chip within the package, compatibility may be ensured without requiring additional redesign.

According to any one of the means for solving the problems of the present invention, a semiconductor package includes a package substrate in which a chip-to-chip communication line is disposed between semiconductor dies, thereby enabling the integration of heterogeneous chips within a single package.

According to any one of the means for solving the problems of the present invention, a semiconductor package can improve electromagnetic interference (EMI) shielding performance of chip-to-chip communication and enhance signal integrity by including a capacitor that alternating current (AC)-couples different semiconductor dies.

According to any one of the means for solving the problems of the present invention, a semiconductor package can enhance integration density by including an AC-coupling capacitor disposed in a package substrate or an interposer.

According to any one of the means for solving the problems of the present invention, a semiconductor package can transmit high-quality signals without distortion or loss over a wide bandwidth by including an AC communication line in which a capacitor is AC-coupled and a communication line in which a conductive wiring is direct current (DC)-coupled.

According to any one of the means for solving the problems of the present invention, a semiconductor package can improve compatibility between semiconductor dies with different frequency characteristics and enhance flexibility in package design and system scalability by including channels for various signal bands.

The effects obtainable from the present invention are not limited to the effects mentioned above, and other effects not mentioned will be clearly understood by those skilled in the art to which the present invention pertains from the following description.

While the embodiments of the present invention have been described in detail above with reference to the accompanying drawings, the present invention is not necessarily limited to these embodiments, and various changes and modifications may be made without departing from the technical spirit of the present invention. Accordingly, the embodiments disclosed herein are to be considered descriptive and not restrictive of the technical spirit of the present invention, and the scope of the technical spirit of the present invention is not limited by these embodiments. Accordingly, the above-described embodiments should be understood to be exemplary and not limiting in any aspect. The scope of the present invention should be construed by the appended claims along with the full range of equivalents to which such claims are entitled.

What is claimed is:

1. A semiconductor package comprising:
a package substrate;
a first semiconductor die disposed on the package substrate;
a second semiconductor die disposed on the package substrate to be spaced apart from the first semiconductor die; and
at least one capacitor disposed on at least one electrical path between the first semiconductor die and the second semiconductor die,
wherein the at least one capacitor includes a first pad or bump connected to the first semiconductor die and a second pad or bump connected to the second semiconductor die, and alternating current (AC)-couples the first semiconductor die and the second semiconductor die.

2. The semiconductor package of claim 1, wherein the at least one capacitor is disposed in the package substrate.

3. The semiconductor package of claim 2, further comprising:
a passivation layer disposed on the at least one capacitor;
a first bridge wiring disposed between the first semiconductor die and the first pad or bump; and
a second bridge wiring disposed between the second semiconductor die and the second pad or bump.

4. The semiconductor package of claim 2, wherein the first pad or bump and the second pad or bump are disposed on the at least one capacitor, and
the first pad or bump is directly connected to a bump or pad disposed below the first semiconductor die, or the second pad or bump is directly connected to a bump or pad disposed below the second semiconductor die.

5. The semiconductor package of claim 1, further comprising an interposer disposed between the first and second semiconductor dies and the package substrate,
wherein the at least one capacitor is disposed in the interposer.

6. The semiconductor package of claim 5, wherein the at least one capacitor is embedded in the interposer, and
the interposer includes at least one of a first via formed to pass through between a bump or pad disposed below the first semiconductor die and the first pad, and a second via formed to pass through between a bump or pad disposed below the second semiconductor die and the second pad.

7. The semiconductor package of claim 1, wherein the at least one capacitor is disposed as a plurality of capacitors on the at least one electrical path, and
the plurality of capacitors disposed on the at least one electrical path are connected in parallel.

8. The semiconductor package of claim 7, further comprising a plurality of switches, each disposed between each of the plurality of capacitors and the first semiconductor die or the second semiconductor die,
wherein each of the plurality of capacitors has a different capacitance.

9. The semiconductor package of claim 1, wherein a plurality of electrical paths are disposed between the first semiconductor die and the second semiconductor die.

10. The semiconductor package of claim 9, further comprising a capacitor chip in which the at least one capacitor is disposed as a plurality of capacitors on a single die,
wherein each of the plurality of electrical paths connects the first semiconductor die and the second semiconductor die through each of the plurality of capacitors included in the capacitor chip.

11. The semiconductor package of claim 9, wherein the at least one capacitor is disposed on at least one of the plurality of electrical paths,
the at least one of the plurality of electrical paths is formed of a conductive wiring, and
the conductive wiring direct current (DC)-couples the first semiconductor die and the second semiconductor die.

12. The semiconductor package of claim 9, wherein the at least one capacitor is disposed on each of the plurality of electrical paths, and
each of the at least one capacitor has a different capacitance.

13. The semiconductor package of claim 12, wherein the first semiconductor die and the second semiconductor die selectively transmit and receive an AC signal through an optimal path among the plurality of electrical paths, and
the optimal path is determined by a frequency of the AC signal and the capacitance.

14. The semiconductor package of claim 1, wherein the first semiconductor die and the second semiconductor die include a serializer and a deserializer, respectively.
